(19) United States
(12) Patent Application Publication
(10) Pub. No.: US 2019/0088504 A1
(43) Pub. Date: Mar. 21, 2019

(54) WAFER LEVEL PACKAGE AND METHOD OF ASSEMBLING SAME

(71) Applicant: NXP B.V., Eindhoven (NL)

(72) Inventor: CHUNG HSIUNG HO, Kaohsiung (TW)

(21) Appl. No.: 15/709,427

(22) Filed: Sep. 19, 2017

(51) Int. Cl. H01L 21/56; H01L 21/48; H01L 23/00

(52) U.S. Cl. CPC H01L 21/561; H01L 21/4853; H01L 24/10; H01L 21/563; H01L 2224/04042; H01L 2224/02311; H01L 2224/0239; H01L 2224/0401; H01L 24/94

(57) ABSTRACT

A method of of assembling semiconductor devices includes attaching semiconductor dies to a carrier, where backsides of the dies are attached to the carrier, and active sides of the dies are face-up. Gaps between lateral sides of the dies are filled with a first molding compound. A redistribution layer (RDL) is formed over the active sides of the dies and the exposed top side of the molding compound, thereby forming an assembly. The assembly is singulated to form individual semiconductor devices. The carrier is formed by pre-molding a mold compound and is an integral part of the final semiconductor devices. Reducing the amount of the second mold compound located between the dies reduces the risk of the assembly warping.

### BACKGROUND OF THE INVENTION

The present invention relates to the packaging of integrated circuits (ICs) and, more particularly, to a method of assembling a Wafer Level Package (WLP) and a wafer level package assembled using the method.

Wafer Level Packaging has become very popular due to the small size of the overall package and lower cost due to not requiring a lead frame or wire bonding. A common method of assembly includes places semiconductor dies face down on a temporary carrier or substrate. The dies and temporary carrier are over-molded with a molding compound using a compression molding process. After molding, the carrier or substrate is removed. The molded dies then are turned over, leaving the die active surfaces exposed. A build-up structure is formed over the dies and conductive balls attached to the built-up structure. The assembly is singulated, thereby providing individual devices.

FIG. 1 is an enlarged cross-sectional side view illustrating a method of assembling wafer level packages using a conventional assembly process. In a first step, a plurality of semiconductor dies 10 are attached to a temporary carrier or substrate 12, where the dies 10 are placed face-down (i.e., active side down) on the substrate 12. The carrier 12 typically is made of steel. Next, a compression molding process is performed such that the back and side surfaces of the dies 10 are covered with a molding compound 14, and the molding compound is cured. Next, the temporary carrier 12 is removed, and then a fan-out or redistribution layer 16 is formed over the dies 10 and solder balls 18 are attached to the redistribution layer 16.

FIG. 2 is a cross-sectional side view of the plurality of dies 10 disposed face-up in the molding compound 14 after the over-molding process and removal of the temporary carrier or substrate 12. As can be seen, the back sides of the dies 10 are covered by a relatively thick layer of the molding compound 14. Unfortunately, due to molding compound shrinkage after curing, as well as a coefficient of thermal expansion mismatch between the dies 10 and the molding compound 14, the assembly is subject to warping, as shown.

It would be desirable to have a method of assembling WLP type devices that are less susceptible to warpage during the assembly process.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention. For example, the size and dimensions of some elements have been exaggerated for ease of understanding and explanation.

FIG. 1 is an enlarged cross-sectional side view illustrating a method of assembling wafer level packages using a conventional assembly process;

FIG. 2 is an enlarged cross-sectional side view illustrating warpage of a strip of dies disposed in a molding compound during a conventional assembly process;

FIG. 3 is a series of enlarged cross-sectional side views illustrating various steps of a method of assembling wafer level packages in accordance with an embodiment of the present invention;

FIG. 4 is an enlarged cross-sectional side view of a semiconductor device in accordance with an embodiment of the present invention; and

FIG. 5 is a series of enlarged cross-sectional side views illustrating various steps of a method of assembling wafer level packages in accordance with another embodiment of the present invention.

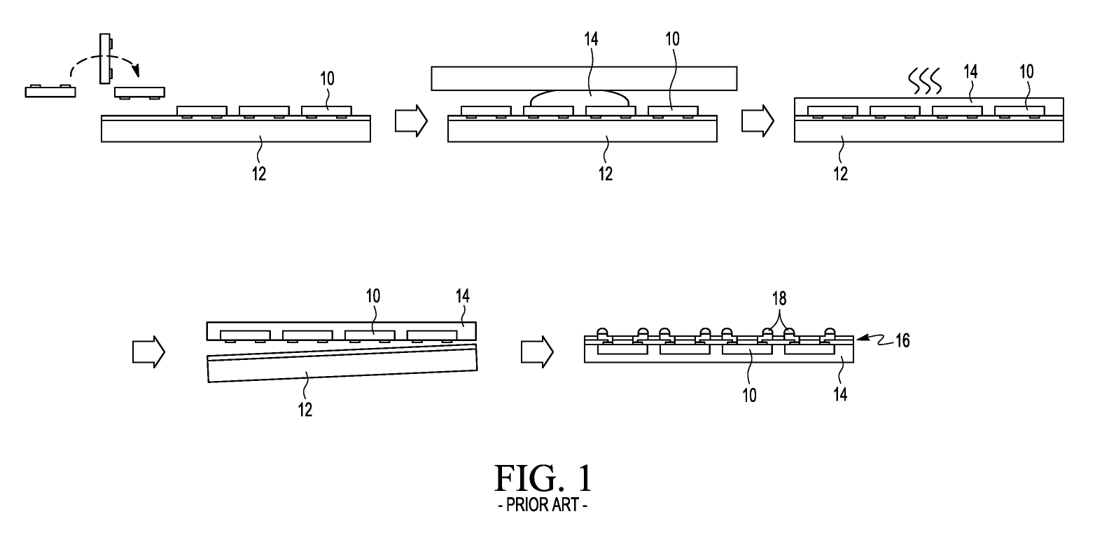

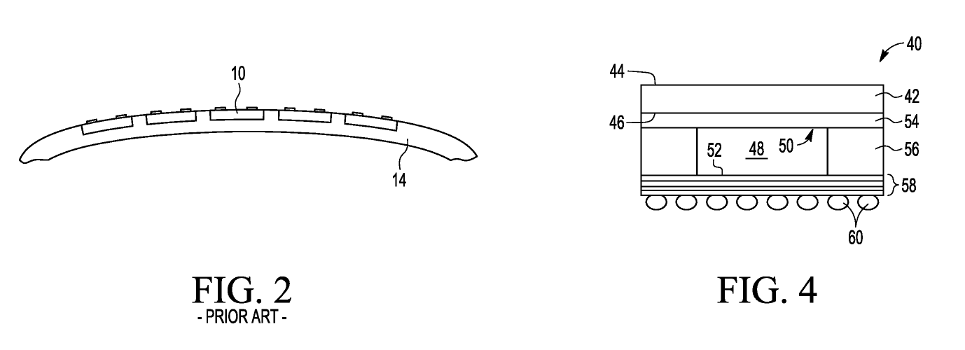

### DETAILED DESCRIPTION OF THE INVENTION

The detailed description set forth below in connection with the appended drawings is intended as a description of a presently preferred embodiment of the invention, and is not intended to represent the only form in which the present invention may be practiced. It is to be understood that the same or equivalent functions may be accomplished by different embodiments that are intended to be encompassed within the spirit and scope of the invention. In the drawings, like numerals are used to indicate like elements throughout.

In one embodiment, the present invention provides a method of assembling a plurality of semiconductor devices, comprising: attaching a plurality of semiconductor dies to a carrier, wherein backsides of the dies are attached to the carrier, and active sides of the dies are face-up; filling gaps between lateral sides of the dies with a first molding compound, wherein a top side of the molding compound is exposed; forming a redistribution layer over the active sides of the dies and the exposed top side of the molding compound, thereby forming an assembly; and singulating the assembly to form the plurality of semiconductor devices, wherein the carrier comprises an integral part of the semiconductor devices.

In another embodiment, the present invention provides a semiconductor device, comprising a first mold compound formed as a carrier having a top surface and a bottom surface, a semiconductor die having a back side attached to the top surface of the first mold compound, a second mold compound formed on the lateral sides of the semiconductor die and covering exposed portions of the top surface of the first mold compound, and a redistribution layer formed over an exposed active side of the semiconductor die.

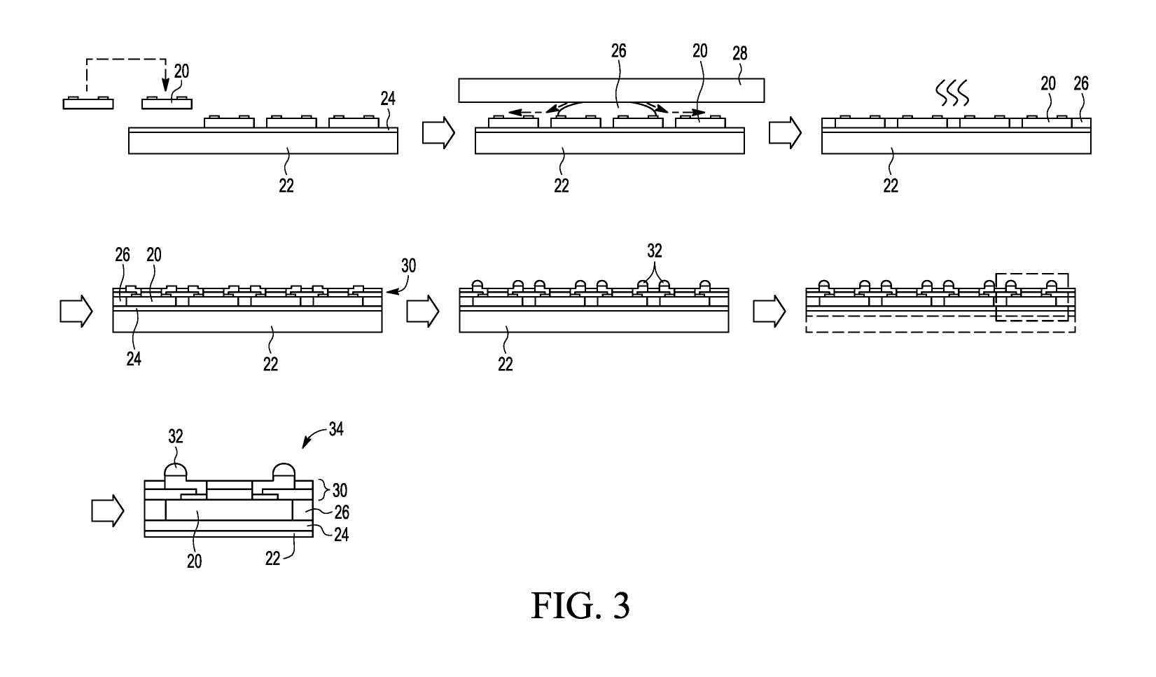

Referring now to FIG. 3, a series of enlarged cross-sectional side views illustrating various steps of a method of assembling wafer level packages in accordance with an embodiment of the present invention is shown. First, a plurality of semiconductor dies 20 are attached to a carrier 22 with an adhesive 24. In the present embodiment, the dies 20 are flip-chip dies and the backsides thereof are attached to the carrier 22 with the adhesive 24, while the top or active sides of the dies 20 face up and are exposed.

The carrier 22 preferably comprises a molding compound and is formed by pre-molding the carrier 22 to a desired shape, such as a square (e.g., to simultaneously make an array of devices) or a rectangle (e.g., to simultaneously make a strip of devices). The dies are attached to the carrier with the adhesive. In one embodiment, the adhesive 24 is a wafer backside coating or backside protection (BSP) tape disposed between the die 20 and the carrier 22. Wafer BSP tape is known in the art and applied to a backside of a wafer to prevent infrared (IR) rays from harming the underlying circuitry. Although wafer BSP tape is presently preferred, a die bond adhesive also could be used to attach the dies 20 to the carrier 22.

After securing the dies 20 to the pre-molded carrier 22, a molding process, such as compression molding, is performed to fill gaps between the lateral sides of the dies 20 with a molding compound 26. A release film 28 is placed over the tops of the dies 20 so that the top sides of the dies 20 are not covered with the molding compound 26, and instead are exposed. Preferably a top side of molding compound 26 is level with the top, active sides of the dies 20. After applying the molding compound 26, a post-mold curing step is performed to cure the molding compound 26. In a presently preferred embodiment, the carrier 22 and the molding compound 26 comprise the same material. An example post-mold curing process comprises baking the assembly in a curing oven for about 90 minutes at 145° C.)

After curing, a redistribution layer (RDL) 30 is formed over the active sides of the dies 20 and the exposed top side of the molding compound 26. In one embodiment, the RDL 30 comprises a first polyimide layer, a metal layer, a second polyimide layer, and an underbump metallization layer, such that bonding pads of the plurality of dies are electrically coupled to exposed metal ends of the RDL 30. Conductive balls 32 then are attached to the exposed metal ends of the RDL 30, as is known in the art, thereby providing a fan-out from the die bonding pads to the conductive balls 32. In one embodiment, the conductive balls 32 comprise solder balls having a ball size of approximately 300 um before reflow.

The assembly, including the dies 20, the pre-molded carrier 22, the adhesive 24, the RDL 30 and the conductive balls 32 may be thinned by removing a portion of an exposed surface of the carrier 22, such as by grinding or cutting, as desired.

Singulation is then performed, such as with a saw as is known in the art, to form a plurality of packaged semiconductor devices 34. It is of particular note that the carrier 22 is an integral part of the finished devices 34. It also will be understood by those of skill in the art that the conductive balls 32 may be attached to the exposed metal ends of the RDL 30 either before or after the singulation step.

FIG. 4 is an enlarged cross-sectional side view of a semiconductor device 40 in accordance with an embodiment of the present. The semiconductor device 40 comprises a first mold compound 42 that is pre-formed as a carrier having an outer surface 44 and an inner surface 46, and a semiconductor die 48 having a backside 50, which is the non-active side, and a front, active side 52. The backside 50 of the die 48 is affixed to the inner surface 46 of the first mold compound 42 with an adhesive 54. A second mold compound 56 is formed on the lateral sides of the semiconductor die 48, and, as shown in FIG. 4, the second mold compound 56 also is in contact with the inner surface 46 of the first mold compound 42 by way of the adhesive 54.

A RDL 58 is formed over the front, active side 52 of the semiconductor die 48 as well as over a temporarily exposed surface of the second mold compound 56. In one embodiment, the RDL 58 comprises at least a first polyimide layer, a metal layer, a second polyimide layer, and an underbump metallization layer, and is formed using known techniques such that bonding pads on the active side 52 of the die 48 are electrically coupled to exposed metal ends of the RDL 58. In other embodiments, the RDL 58 comprises a plurality of dielectric layers and redistribution layers deposited on a front side of the die to form electrical connections between bond pads on the die and redistributed solder bump bond pads of the RDL 58. Conductive balls 60 are attached to the exposed metal ends of the RDL 58, thereby providing IO access to/from the die 48 and its underlying circuitry.

Thus, the device 40 comprises the die 48 having the second mold compound 56 on its lateral sides, and the first mold compound 42 and adhesive 54 covering both the die back side 50 and a top surface of the second mold compound 56. The RDL 50 covers the die bottom side 52 and the bottom surface of the second mold compound 50. The adhesive 54 may comprise, for example, glue or a backside protection adhesive applied with a tape. The top and bottom surfaces of the second mold compound 56 preferably are level or planar with the respective back and front sides 50, 52 of the die 48.

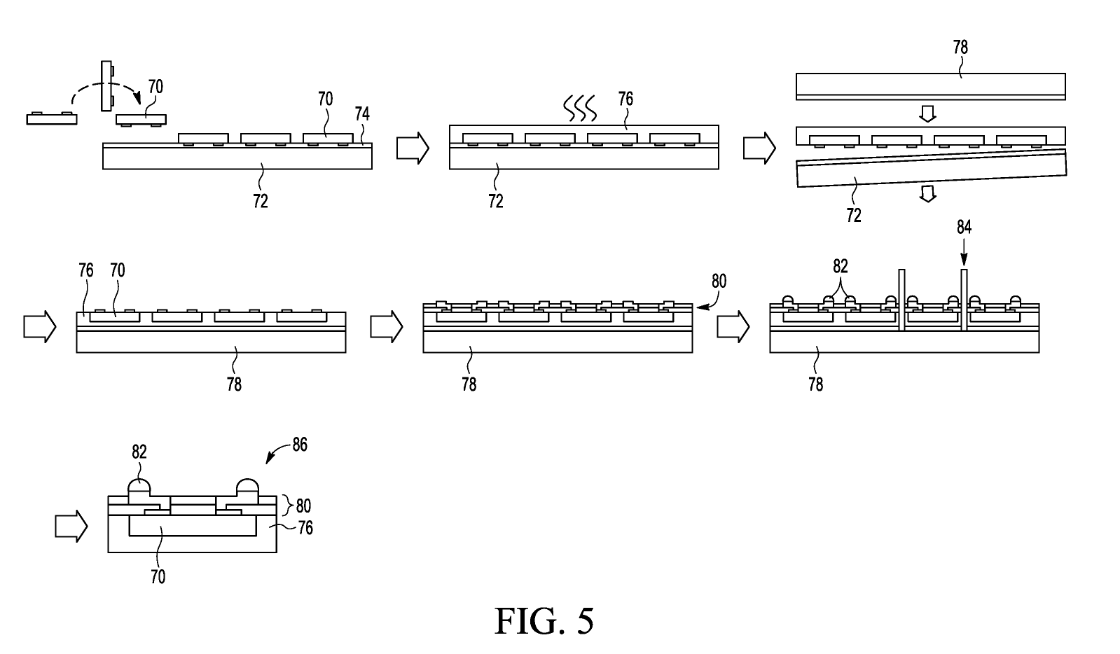

FIG. 5 is a series of enlarged cross-sectional side views illustrating a method of assembling wafer level packages in accordance with another embodiment of the present invention. First, a plurality of semiconductor dies 70 are attached to a first carrier 72 with an adhesive 74. In this embodiment, the dies 70 are flip-chip dies, but unlike in the first embodiment, here the dies 70 are attached to the first carrier 72 by their front or active sides, and the backsides of the dies 20 are exposed. The first carrier 72 may comprise a temporary glass or steel carrier, as is known in the art, for example, which is unlike the carrier 22 (FIG. 3), which is formed of pre-molded epoxy mold compound, because the first carrier 72 is just a temporary carrier and is not part of the final package. The dies 70 may be attached to the first carrier 72 with an adhesive 74, which preferably comprises a double-sided thermo-release tape. The tape is releasable at around 180° C.

An overmolding process (including post-mold curing) is performed next to cover the dies 70 with a liquid molding compound 76, that can be cured post-molding at a temperature of 145° C. Next, the first carrier 72 is removed, exposing the active surfaces of the dies 70, and a second carrier 78 is affixed to the opposing side of the molded assembly. The first carrier 72 can be removed (de-bonding step) by subjecting the assembly to a temperature of 185° C. The second carrier 78, like the first carrier 72, is just a temporary carrier, so may comprise a known glass carrier. It is presently preferred that the molded assembly is attached to the second carrier 78 before the first carrier 72 is removed to prevent the assembly from warping.

Removal of the first carrier 72 exposes the active surfaces of the dies 70, and a RDL 80 is formed over the dies 70. The RDL 80 includes a number of layers sufficient to form a fan-out as depends on the number of IOs and the size of the die. This assembly (dies 70, mold compound 76, RDL 80, and solder balls 82) is singulated using a saw blade 84 along saw streets located between the dies 70. The second carrier 78 then is removed such that a plurality of packaged devices 86 are provided. By performing the assembly method using the first and second carriers 72, 78, the assembly is at all times supported by at least one of the carriers, and therefore warpage is prevented.

As is evident from the foregoing discussion, the present invention provides a semiconductor device and a method of assembling the semiconductor device. The invention has the following benefits, less liquid mold compound between the semiconductor dies, less stress/warpage after molding and post-mold cure, greater strength to protect against warpage during assembly, pre-molded carrier as part of the finished package, and a thick carrier to provide adequate strength to support the dies and the RDL.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiments disclosed, but covers modifications within the spirit and scope of the present invention as defined by the appended claims.

1-13. (canceled)

14. A semiconductor device, comprising:
a first mold compound formed as a carrier having a top surface and a bottom surface;
a semiconductor die having a back side attached to the top surface of the first mold compound;
a second mold compound formed on the lateral sides of the semiconductor die and covering exposed portions of the top surface of the first mold compound, wherein the second mold compound has a top surface that is level with the active side of the die; and
a redistribution layer formed over an exposed active side of the semiconductor die, wherein the redistribution layer extends over the top surface of the second mold compound.

15. The semiconductor device of claim 14, further comprising a plurality of conductive balls attached to the redistribution layer, wherein the conductive balls are electrically connected to respective bonding pads on the active side of the semiconductor die by way of the redistribution layer.

16. The semiconductor device of claim 15, wherein the redistribution layer comprises a first polyimide layer, a metal layer, a second polyimide layer, and an underbump metallization layer, wherein bonding pads of the semiconductor die are electrically coupled to exposed metal ends of the redistribution layer, and the conductive balls are attached to the exposed metal ends.

17. (canceled)

18. (canceled)

19. The semiconductor device of claim 14, further comprising an adhesive that secures the die to the first mold compound.

20. The semiconductor device of claim 19, wherein the adhesive comprises a wafer backside coating tape, and wherein the coating tape separates the die from the first mold compound.
